(19) United States
(12) Patent Application Publication
(10) Pub. No.: US 2007/0067696 A1
(43) Pub. Date: Mar. 22, 2007

(54) System, transmitter, receiver, method, and computer program product for structured interleaved Zigzag coding

(75) Inventors: Tejas Bhatt, Irving, TX (US); Victor Stolpman, Irving, TX (US); Dennis McCain, Lewisville, TX (US)

Correspondence Address: ALSTON & BIRD LLP, BANK OF AMERICA PLAZA, 101 SOUTH TRYON STREET, SUITE 4000, CHARLOTTE, NC, 28280-4000, US

(73) Assignee: NOKIA CORPORATION

(21) Appl. No.: 11/222,008

(22) Filed: Sep. 8, 2005

(51) Int. Cl. H03M 13/00

(52) U.S. Cl. 714/758

(57) ABSTRACT

A system, transmitter, receiver, method, and computer program product are provided in which a plurality of structured interleavers permute data bits arranged in a data bit matrix for Zigzag encoding. For each interleaver, the data bits in each column of the data bit matrix are cyclically shifted, with the amount of the shift being predefined and different for each column. In addition to the cycle shift, each column may be bit reverse ordered, and entire columns may be swapped. The interleaved data bit matrix may then be encoded using a Zigzag encoder to generate parity bits that may be transmitted, along with the data bits, from a transmitter to a receiver where the data may be iteratively decoded.

### FIELD OF THE INVENTION

Embodiments of the invention generally relate to communication techniques and, more particularly, relate to error coding and error correction of transmitted data using parity bits.

### BACKGROUND OF THE INVENTION

Environmental interference in a wireless communication system or physical defects in the communication medium of a wired communication system may cause random bit errors (e.g., a transmitted “1” is received as “0” and vice versa) during data transmission. Error coding is a method of detecting and correcting these random bit errors to ensure information is transferred accurately from the source (i.e., the transmitter) to the destination (i.e., the receiver). Error coding typically uses mathematical formulas to encode the data bits at the transmitter into longer bit words (i.e., code words) to be transmitted to the receiver. The code word typically includes the data bits and one or more parity bits. The code word can then be decoded at the receiver to retrieve the information. The parity bits in the code word enable the receiver to use the decoding process to determine if the communication medium introduced errors. Depending on the coding scheme, the parity bits may also enable the receiver to correct transmission errors so that the data does not need to be retransmitted. Many different error coding schemes are known, with the different schemes chosen depending on the types of errors expected, the expected error rate, and the feasibility of data retransmission. However, tradeoffs between bandwidth and coding overhead, coding complexity, and allowable coding delay must be considered for each application.

One method of error coding is termed Zigzag coding. Zigzag code may be viewed as modified single parity check (SPC) code. The encoding procedure for zigzag code may be visualized by first arranging total of N₁ information data bits in a matrix of I rows and J columns, where N₁=I*J. The data bit matrix may be designated D₁. The data bits in the matrix may be designated as d_{i,j}, where I is the row number and J is the column number. As such, the first row of data bits may be designated d_{1,1}, d_{1,2}, d_{1,3}, and so on through d_{1,J}. The second row of data bits may be designated d_{2,1}, d_{2,2}, d_{2,3}, and so on through d_{2,J}. The bottom (or I^{th}) row of data bits may be designated d_{I,1}, d_{I,2}, d_{I,3}, and so on through d_{I,J}. As such, the data bit matrix D₁ may be expressed as

$${D}_{1} = [ \begin{matrix}{d}_{1 , 1} & {d}_{1 , 2} & ⋯ & {d}_{1 , J} \\ {d}_{2 , 1} & {d}_{2 , 2} & ⋯ & {d}_{2 , J} \\ ⋮ & ⋮ & ⋮ & ⋮ \\ {d}_{I , 1} & {d}_{I , 2} & ⋯ & {d}_{I , J}\end{matrix} ] .$$

A parity bit may then be calculated for the first row of data bits in the data bit matrix, using any known parity technique. The parity bit for the first row may be designated p₁. A parity bit may then be calculated for the combination of the first two rows (or for the combination of p₁ and the second row, which produces the same result). The parity bit for the first two rows may be designated p₂. A parity bit may then be calculated for the combination of the first three rows (or for the combination of p₂ and the third row, which produces the same result). The parity bit for the first three rows may be designated p₃. The final parity bit, which is calculated for the combination of all rows (or for the combination of p_{I-1} and the I^{th} row, which produces the same result), may be designated p₁. This process produced a complete set of parity bits, which may be designated P₁, for the data bit matrix D₁. As such, the complete set of parity bits may be expressed as

$${P}_{1} = [ \begin{matrix}{p}_{1} \\ {p}_{2} \\ ⋮ \\ {p}_{I}\end{matrix} ] , where {p}_{1} = {\sum }_{j = 1}^{J} d ( 1 , j ) mod 2$$

and

$${p}_{i} = {\sum }_{j = 1}^{J} d ( i , j ) + p ( i - 1 ) mod 2 , i = 2 , 3 , … , I .$$

Concatenated Zigzag codes are a class of modified single parity-check (SPC) codes, where different sets of parity checks are computed with different permutations of the data bits. These different permutations are performed by interleavers, and the process of permuting the data is termed interleaving. The interleavers are typically designated as πₖ, where k is the index of an interleaver, such that the interleavers may be designated as π₁, π₂, π₃, and so on through π_{K}, where K is the total number of interleavers, thus generating a total of K different interleaved data bit sequences. A set of parity bits may be calculated from each of the interleaved sequences, with the different parity sets respectively designated as P₁, P₂, P₃, and so on through P_{K}, with each set of parity bits containing I parity bits. Hence, information data of length N₁=I*J is encoded using K different interleaved data patterns, and the overall code rate of the Zigzag code is

$$R = \frac{J}{J + K}$$

and the codeword length is N_{C}=I×(J+K). Each of the K encoders may be termed a constituent encoder.

Zigzag codes are decoded using an iterative decoder (similar to turbo codes or Low Density Parity Check (LDPC) codes). Each decoding iteration can be further partitioned into K sub-iterations. In a sub-iteration, the decoder may implement a Bahl-Cocke-Jelinek-Raviv (BCJR) algorithm, a Max-Log-A Posteriori Probability (“Max-Log-APP”) Algorithm (“MLA”), or any other appropriate soft-input/soft-output (SISO) decoding algorithm to compute the extrinsic messages on the information bits from the information available from the parity check equations and extrinsic information from all other constituent codes. The updated messages may then be passed to next constituent code after appropriate interleaving and de-interleaving operations.

For Zigzag codes, the extrinsic message passing via interleaver/de-interleaver affects the achievable data throughput. In general, random interleavers are used for concatenated Zigzag codes. That is to say that the data in the data bit matrix is randomly permuted. The use of random interleavers typically provides the necessary interleaver gain to accurately detect and correct errors. However, random interleavers are typically not suitable for efficient encoder/decoder (CODEC) implementation due to lack of any structure. Lack of structure may affect the implementation of interleaver and Zigzag decoder in general and may make them unsuitable for high throughput applications, such as Ultra Wideband (UWB) or IEEE 802.11n communication standards which require the decoder to run at 500 Mbps (megabits per second) to 1 Gbps (gigabits per second). The use of a random interleaver requires that the interleaver sequence be stored in memory for real time CODEC implementation, which increases memory requirements and overall implementation complexity. This also requires that the decoder access the memory repeatedly during the decoding process, which may not be feasible at very high data rates. The use of a random interleaver also typically prevents parallel encoding/decoding and prevents the encoding/decoding from being implemented in hardware.

### BRIEF SUMMARY OF THE INVENTION

A system, transmitter, receiver, method, and computer program product are therefore provided in which a plurality of structured interleavers permute data bits arranged in a data bit matrix for Zigzag encoding. For each interleaver, the data bits in each column of the data bit matrix are cyclically shifted, with the amount of the shift being predefined and different for each column. In addition to the cyclic shift, each column may be bit reverse ordered, and entire columns may be swapped. The interleaved data bit matrix may then be encoded using a Zigzag encoder to generate parity bits that may be transmitted, along with the data bits, from a transmitter to a receiver where the data may be iteratively decoded.

In this regard, a system for concatenated zigzag coding of a plurality of data bits arranged in a matrix of rows and columns comprises a transmitter and a receiver. The transmitter is capable of interleaving the data bits by shifting the data bits in each of the columns by a different respective one of a plurality of predefined numbers. Each predefined number is different from all other numbers in the plurality of predefined numbers. The transmitter is further capable of generating the parity bits from the interleaved data bits using a zigzag encoder and transmitting the generated parity bits and the data bits. The receiver is capable of receiving the parity bits and the data bits, and decoding the received parity bits to detect or correct any errors in the received data bits.

The transmitter may be further capable of interleaving the data bits by bit reverse ordering the data bits in each of the columns. Additionally, the transmitter may be further capable of interleaving the data bits by swapping at least two columns of data bits. The transmitter may shift the data bits by cyclically shifting the data bits.

In one embodiment, the generated parity bits are a first set of parity bits, and the transmitter is further capable of interleaving the data bits a second time by shifting the data bits in each of the columns by a different respective one of a second plurality of predefined numbers. Each of the second plurality of predefined numbers is less than or equal to a total number of rows in the matrix. Each one of the second plurality of predefined numbers is different from all other numbers in the second plurality of predefined numbers. And each one of the second plurality of predefined numbers is different than the one of the first plurality of predefined numbers used to shift the data bits in a corresponding column. The transmitter may be further capable of generating a second set of parity bits from the second interleaved data bits using a zigzag encoder.

The transmitter may define the first and second pluralities of predefined numbers using the equation S^{k}=mod([k, k+1, . . . J, 1, 2, . . . k−1]×Pₖ, I), in which k is the number of times the data bits are interleaved, J is the number of columns in the data bit matrix, I is the number of rows in the data bit matrix, and Pₖ is prime relative to I and less than I. Alternatively, the transmitter may define the first and second pluralities of predefined numbers by a shift matrix, in which the number of columns in the shift matrix are equal to the number of columns in the data bit matrix, the number of rows in the shift matrix are equal to the number of times the data bits are interleaved, and each number in each column of the shift matrix is different from all other numbers in each respective column.

In addition to the system for concatenated zigzag coding of a plurality of data bits arranged in a matrix of rows and columns described above, other aspects of the invention are directed to corresponding transmitters, receivers, methods, and computer program products for concatenated zigzag coding of data bits.

### BRIEF DESCRIPTION OF THE SEVERAL VIEWS OF THE DRAWING(S)

Having thus described the invention in general terms, reference will now be made to the accompanying drawings, which are not necessarily drawn to scale, and wherein:

FIG. 1 is a schematic block diagram of a wireless communication system, according to an exemplary embodiment of the invention;

FIG. 2 is a functional block diagram of a transmitter with multiple interleavers and Zigzag encoders, according to an exemplary embodiment of the invention;

FIG. 3A illustrates the operation of cyclically shifting each column of a data bit matrix, according to an exemplary embodiment of the invention;

FIG. 3B illustrates the result of cyclically shifting each column of a data bit matrix, according to an exemplary embodiment of the invention;

FIG. 3C illustrates the operation of swapping shift numbers in a shift matrix, according to an exemplary embodiment of the invention;

FIG. 4 is a functional block diagram of a receiver with an iterative Zigzag decoder, according to an exemplary embodiment of the invention; and

FIG. 5 is a flowchart of the operation of concatenated zigzag coding of data bits using a structured interleaver, according to an exemplary embodiment of the invention.

### DETAILED DESCRIPTION OF THE INVENTION

Embodiments of the invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art. Like numbers refer to like elements throughout.

As shown and described below, the system, transmitter, receiver, method, and computer program product of exemplary embodiments of the invention operate to encode data using a regular structured Zigzag code interleaving scheme. It should be understood, however, that the system, transmitter, receiver, method, and computer program product of exemplary embodiments of the invention may be equally applicable to generalized (i.e., irregular) structured Zigzag codes, without departing from the spirit and scope of the invention. It should further be understood that the transmitting and receiving entities may be implemented into any of a number of different types of transmission systems that transmit coded or uncoded digital transmissions over a radio interface. The system, transmitter, receiver, method, and computer program product of embodiments of the invention will be primarily described in conjunction with wireless communication systems. It should be further understood, however, that embodiments of the invention can be utilized in conjunction with a variety of wired or wireless communication systems.

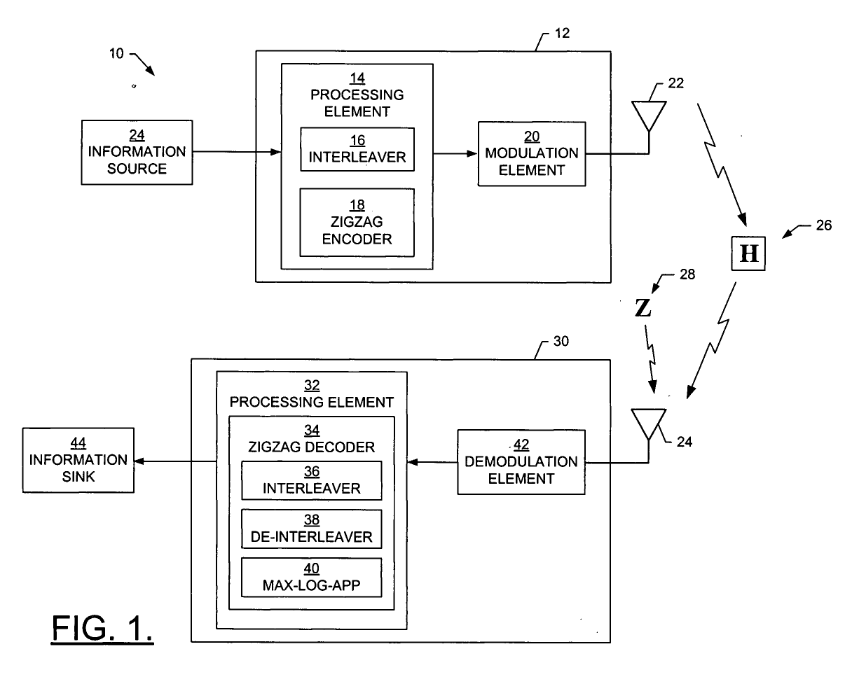

Referring to FIG. 1, an illustration of a schematic block diagram of a communication system 10 is provided, in accordance with an exemplary embodiment of the invention. As shown, the system includes a transmitter 12 and a receiver 30. The transmitter 12 may receive data to be transmitted from an information source 24. The data bits are arranged into a data bit matrix that has I rows and J columns (I×J), such as by the processing element 14. While the operation of the structured interleaver will be described in conjunction with having the data bits arranged into a data bit matrix, it should be appreciated that the data bits may be operated on (interleaved and coded) as if the data bits were arranged into a matrix, even though the data bits may be operated on serially. For example, every Jth bit may be treated as if it were in a column and a parity bit may be generated for every J bits. The data bit matrix is interleaved by the interleaver 16, using a structured interleaver technique as discussed in detail below. The interleaving may include different cyclic shifts of each column, bit reverse ordering of each column, and swapping two or more complete columns. Generally, the different interleaver operations (shift, bit reverse order, and swap) may be performed in any order. The interleaved data bit matrix is then encoded by the Zigzag encoder 18, using a known Zigzag encoding technique. The encoding generates a set of parity bits. As discussed below, the data bits may be interleaved and encoded multiple times, using a different interleaver each time. The data bits and the parity bits are then modulated by the modulation element 20 and transmitted via the antenna 22 over the channel 26 (“H”). Additive white Gaussian noise (“Z”) 28 is typically added to the transmitted signal, which may cause random bit errors. The data is received at the receiver 30 by the antenna 24, and the received data is demodulated by the demodulation element 42. The data is then decoded, such as by the Zigzag decoder 34 of processing element 32. The processing element will typically use a known Zigzag decoding technique, using an interleaver 36, a de-interleaver 38, and a SISO decoding algorithm such as a Max-Log-APP algorithm 40.

The communication system 10 provides for radio communication between two communication stations, such as the transmitter 12 and the receiver 30, by way of radio links formed therebetween. The communication system can be configured to operate in accordance with one or more of a number of different types of communication protocols. For example, the communication system may be configured to operate in accordance with IS-95 (CDMA), cdma2000, Universal Mobile Telephone System (UMTS) employing Wideband Code Division Multiple Access (WCDMA) radio access technology, 1X-EVDO (TIA/EIA/IS-856), 1X-EVDV, ultra wideband (UWB), wireless local area network (LAN), WiMax, and/or any suitable wireless or wireline communication protocol. It should be understood that operation of the exemplary embodiment of the invention is similarly also possible in other types of radio, and other, communication systems without departing from the spirit and scope of the invention.

As described herein, the transmitter and receiver may each include application(s) to provide the described functionality with the application(s) typically comprised of software operated by the respective entities. It should be understood, however, that any one or more of the client applications described herein can alternatively comprise firmware or hardware, without departing from the spirit and scope of the invention. Generally, then, the network entities (e.g., transmitter 12, receiver 30) of exemplary embodiments of the invention can include one or more logic elements for performing various functions of one or more client application(s). As will be appreciated, the logic elements can be embodied in any of a number of different manners. In this regard, the logic elements performing the functions of one or more client applications can be embodied in an integrated circuit assembly including one or more integrated circuits integral or otherwise in communication with a respective network entity or more particularly, for example, a processor or controller of the respective network entity. The design of integrated circuits is by and large a highly automated process. In this regard, complex and powerful software tools are available for converting a logic level design into a semiconductor circuit design ready to be etched and formed on a semiconductor substrate. These software tools, such as those provided by Avant! Corporation of Fremont, Calif., and Cadence Design, of San Jose, Calif., automatically route conductors and locate components on a semiconductor chip using well established rules of design as well as huge libraries of pre-stored design modules. Once the design for a semiconductor circuit has been completed, the resultant design, in a standardized electronic format (e.g., Opus, GDSII, or the like) may be transmitted to a semiconductor fabrication facility or “fab” for fabrication.

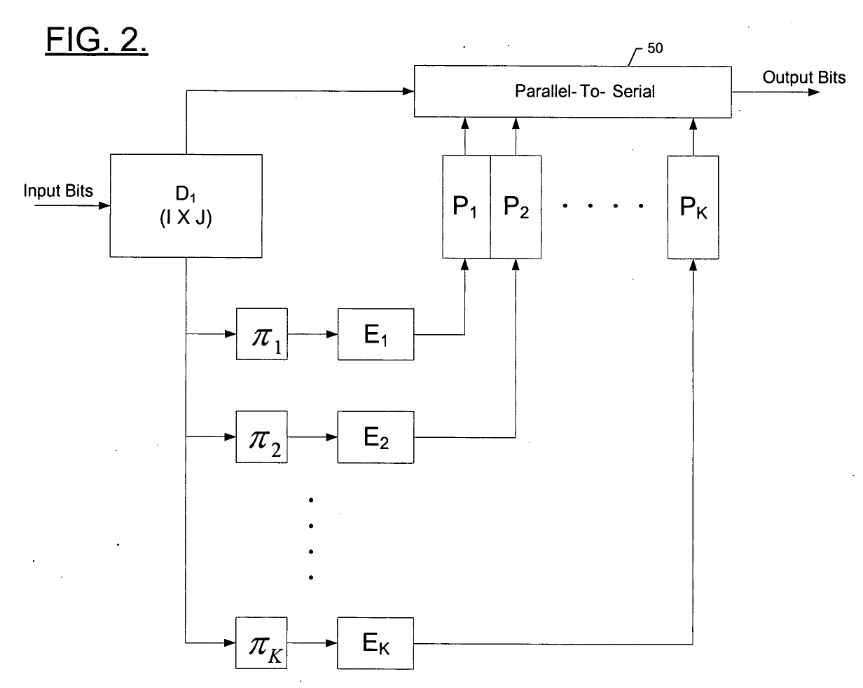

Referring now to FIG. 2, a functional block diagram of a transmitter with multiple interleavers and Zigzag encoders is illustrated, according to an exemplary embodiment of the invention. The information bits are arranged in a data bit matrix D₁, with I rows and J columns (I×J) and with the bits filled in row-wise (i.e., the data bits are arranged in the first row, then the second row, and so on). The data bit matrix is permuted by one or more interleavers. In FIG. 2, the interleavers are designated as π₁, π₂, and so on to π_{K}, such that there are K interleavers illustrated. Each interleaver typically performs a different permutation of the data bit matrix. Generally, the ability to detect and correct errors increases as the number of interleavers increases, however the incremental improvement in the ability to detect and correct errors diminishes with each additional interleaver. In one embodiment of the invention, four different interleavers are used (which would be designated π₁, π₂, π₃, and π₄). The permuted data bit matrix from each interleaver is encoded by a corresponding Zigzag encoder (E₁, E₂, and so on to E_{K} in FIG. 2), to generate a corresponding set of parity bits (P₁, P₂, and so on to P_{K} in FIG. 2). Each set of parity bits typically comprises a parity bit for each row in the data bit matrix, thus a total of I×K parity bits are generated. The data bit matrix and the sets of parity bits are converted from parallel to serial by converter 50, and then modulated and transmitted.

The operation of a single interleaver (π_{K}) will be described in detail, according to one embodiment of the invention. As illustrated in FIG. 2, the data bits are arranged into a data bit matrix (D₁), that may be expressed as

$${D}_{1} = [ \begin{matrix}{d}_{1 , 1} & {d}_{1 , 2} & ⋯ & {d}_{1 , J} \\ {d}_{2 , 1} & {d}_{2 , 2} & ⋯ & {d}_{2 , J} \\ ⋮ & ⋮ & ⋮ & ⋮ \\ {d}_{I , 1} & {d}_{I , 2} & ⋯ & {d}_{I , J}\end{matrix} ] .$$

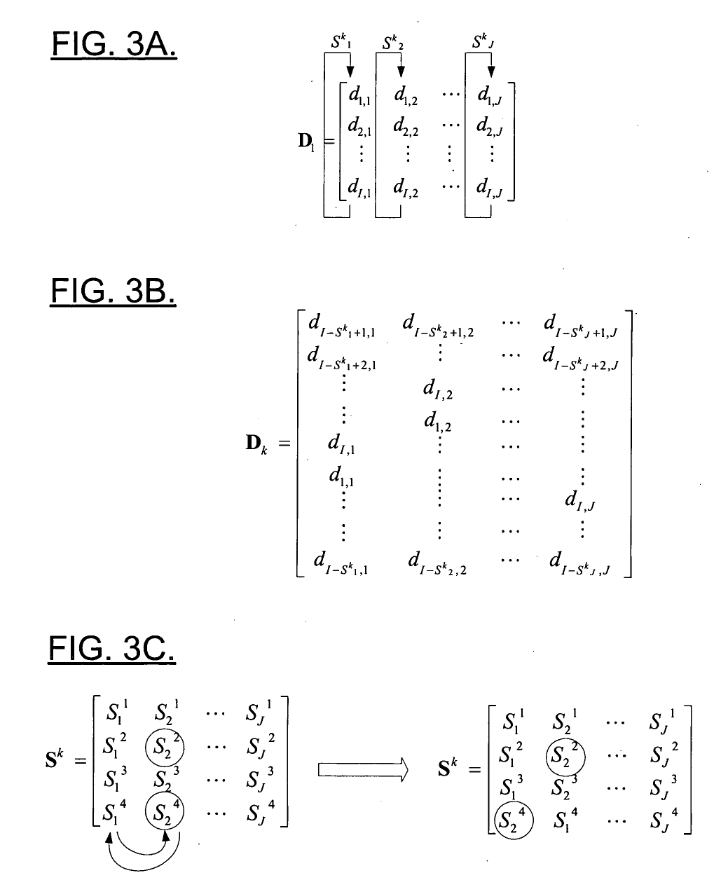

The interleaver operates on each column, and each of the J columns may be cyclically shifted with a unique shift. As such, a total of J shifts are specified and a total of I unique shifts are possible. The set of unique numbers used to shift the columns may be expressed as S^{k}=[S₁^{k}, S₂^{k} . . . S_{J}^{k}], where Sⱼ is a predefined shift number, and where S₁^{k} is the number used by the K^{th} interleaver to shift the first column, S₂^{k} is the number used by the K^{th} interleaver to shift the second column, and so on through to S_{J}^{k}, which is the number used by the K^{th} interleaver to shift the J^{th} column. Ensuring that each number in the set S^{k} is unique ensures that the interleaver gain produced by the structured interleaver of embodiments of the invention is similar to the interleaver gain produced by a random interleaver. The shift that is performed by the interleaver on each column of the data bit matrix will be described herein as a cyclic shift, although other known types of shifts may be used without departing from the spirit and scope of the invention. FIG. 3A illustrates the operation of shifting each column of data bit matrix D₁. The first column is cyclically shifted by the number designated as S₁^{k}, the second column is cyclically shifted by the number designated as S₂^{k}, and so on through to the J^{th} column cyclically shifted by the number designated as S_{J}^{k}. FIG. 3B illustrates the result of cyclically shifting D₁ by the set of numbers S^{k}.

To further illustrate the operation of shifting the columns of the data bit matrix, an exemplary 4×4 matrix is expressed as

$${D}_{1} = [ \begin{matrix}{d}_{1 , 1} & {d}_{1 , 2} & {d}_{1 , 3} & {d}_{1 , 4} \\ {d}_{2 , 1} & {d}_{2 , 2} & {d}_{2 , 3} & {d}_{2 , 4} \\ {d}_{3 , 1} & {d}_{3 , 2} & {d}_{3 , 3} & {d}_{3 , 4} \\ {d}_{4 , 1} & {d}_{4 , 2} & {d}_{4 , 2} & {d}_{4 , 4}\end{matrix} ] .$$

This matrix may be shifted by an exemplary set of shift numbers expressed as S¹=[4, 3, 1, 2], such that the first column is shifted by 4, the second column is shifted by 3, the third column is shifted by 1, and the fourth column is shifted by 2. Note that each number in the set is unique. Shifting the columns of the data bit matrix as described above would result in the following interleaved data bit matrix:

$${D}_{1} = [ \begin{matrix}{d}_{1 , 1} & {d}_{4 , 2} & {d}_{2 , 3} & {d}_{3 , 4} \\ {d}_{2 , 1} & {d}_{1 , 2} & {d}_{3 , 3} & {d}_{4 , 4} \\ {d}_{3 , 1} & {d}_{2 , 2} & {d}_{4 , 3} & {d}_{1 , 4} \\ {d}_{4 , 1} & {d}_{3 , 2} & {d}_{1 , 3} & {d}_{2 , 4}\end{matrix} ] .$$

It should be appreciated that any shift amount that is equal to or greater than the number of rows in the matrix would typically result in a shift of the remainder of Sⱼ divide by I. For example, consider the above matrix in which I is equal to 4 (i.e., the matrix has 4 rows). If Sⱼ is 4, the column will be shifted by 0 (i.e., not shifted); if Sⱼ is 5, the column will be shifted by 1; if Sⱼ is 6, the column will be shifted by 2; and so on. Alternatively, each predefined shift number may be interpreted as the modulo of I, thereby resulting in an effective shift of less than I.

In addition to shifting the columns of the data bit matrix, the interleaver may bit reverse order each column. Bit reverse ordering is a data permutation technique in which the binary address of each bit in a column of the data bit matrix is determined, the bits of the binary address are reversed, and the data bits are moved to the location in the column indicated by the reversed binary address. For example, consider the exemplary data bit matrix above, in which the first column contains four data bits (from top to bottom) expressed as d_{1,1}, d_{2,1}, d_{3,1}, and d_{4,1}. The binary address of each data bit would be 00, 01, 10, and 11, respectively. Reversing the address bits results in 00, 10, 01, and 11, respectively. As the reversed binary address for d_{1,1} is not different, d_{1,1} remains in the same position. As the reversed binary address for d_{2,1} has changed from 01 to 10, d_{2,1} is moved from the second position (binary address 01) to the third position (binary address 10). As the reversed binary address for d_{3,1} has changed from 10 to 01, d_{3,1} is moved from the third position (binary address 10) to the second position (binary address 01). As the reversed binary address for d_{4,1} is not different, d_{4,1} remains in the same position. As such, the bit reverse ordered first column would be expressed as (top to bottom) d_{1,1}, d_{3,1}, d_{2,1}, and d_{4,1}. Each column in the data bit matrix may be similarly bit reverse ordered. If the data bit matrix has more than four rows but fewer than nine rows, each data bit will have a three bit binary address that would be reversed. For example, for the first bit in a column the address would not change because the binary address 000 does not change when reversed. For the second bit in a column, the binary address would be reversed from 001 to 100, such that the second bit would be moved to the fifth position. For the third bit in a column, the address would not change because the binary address 010 does not change when reversed. For the fourth bit in a column, the binary address would be reversed from 011 to 110, such that the fourth bit would be moved to the seventh position. This would continue similarly for all data bits in the column. Bit reverse ordering the above shifted data bit matrix would result in the following data bit matrix:

$${D}_{1} = [ \begin{matrix}{d}_{1 , 1} & {d}_{4 , 2} & {d}_{2 , 3} & {d}_{3 , 4} \\ {d}_{3 , 1} & {d}_{2 , 2} & {d}_{4 , 3} & {d}_{1 , 4} \\ {d}_{2 , 1} & {d}_{1 , 2} & {d}_{3 , 3} & {d}_{4 , 4} \\ {d}_{4 , 1} & {d}_{3 , 2} & {d}_{1 , 3} & {d}_{2 , 4}\end{matrix} ] .$$

In addition to shifting and bit reverse ordering the data bit matrix, the interleaver may swap two or more complete columns. For example, the interleaver may swap every two columns, such that columns 1 and 2 are swapped (i.e., the first column is moved to the second column and the second column is moved to the first column), columns 3 and 4 are swapped, and so on. Swapping the columns of the above shifted and bit reverse ordered data bit matrix would result in the following data bit matrix:

$${D}_{1} = [ \begin{matrix}{d}_{4 , 2} & {d}_{1 , 1} & {d}_{3 , 4} & {d}_{2 , 3} \\ {d}_{2 , 2} & {d}_{3 , 1} & {d}_{1 , 4} & {d}_{4 , 3} \\ {d}_{1 , 2} & {d}_{2 , 1} & {d}_{4 , 4} & {d}_{3 , 3} \\ {d}_{3 , 2} & {d}_{4 , 1} & {d}_{2 , 4} & {d}_{2 , 4}\end{matrix} ] .$$

In one embodiment, the interleaver only shifts the columns, but does not bit reverse order or swap the columns. Alternatively, the interleaver may shift the columns and bit reverse order the columns. In another alternative embodiment, the interleaver may shift, bit reverse order, and swap the columns. After the data bit matrix has been interleaved (in this example by shifting, bit reverse ordering, and swapping the columns), the data bit matrix may be encoded by a Zigzag encoder to generate a set of parity bits. In this example, four parity bits (one for each row) would be generated.

As discussed above, a total of K interleavers may be required for a Zigzag code. As such, a set of column shifts must be specified for each interleaver. As discussed above, the set of unique numbers used by one interleaver to shift the columns may be expressed as S^{k}=[S₁^{k}, S₂^{k} . . . S_{J}^{k}] Similarly, the set of numbers (which may be termed a shift matrix) used to shift the columns for the four interleavers may be expressed as

$${S}^{k} = [ \begin{matrix}{S}_{1}^{1} & {S}_{2}^{1} & ⋯ & {S}_{J}^{1} \\ {S}_{1}^{2} & {S}_{2}^{2} & ⋯ & {S}_{J}^{2} \\ {S}_{1}^{3} & {S}_{2}^{3} & ⋯ & {S}_{J}^{3} \\ {S}_{1}^{4} & {S}_{2}^{4} & ⋯ & {S}_{J}^{4}\end{matrix} ] ,$$

where the first row defines the numbers used by the first interleaver to shift the columns of the data bit matrix, the second row defines the numbers used by the second interleaver to shift the columns of the data bit matrix, the third row defines the numbers used by the third interleaver to shift the columns of the data bit matrix, and the fourth row defines the numbers used by the fourth interleaver to shift the columns of the data bit matrix. As discussed above, each of the J columns would typically be cyclically shifted with a unique shift. As such, each number in any particular row of numbers in the shift matrix should be unique. In one embodiment, the shifts in the shift matrix may be computed using prime multiplier and modulo-operation as described in the equation S^{k}=mod([k, k+1, . . . J, 1, 2, . . . k−1]×Pₖ, I), where Pₖ is prime relative to I and less than I. A careful choice of a prime multiplier can avoid similar shifts from one interleaver to another interleaver. Thus, one interleaver can be specified with only one prime number, and a set of K different prime numbers may be used to define the shifts for a set of K interleavers. This enables the data to be coded and decoded by a coder or decoder which can store and/or access the K prime numbers. In contrast, a system which used random interleavers would typically require the coder and decoder to store and/or access I×J×K numbers. Thus, the structured interleaver of embodiments of the invention significantly lowers the storage requirement and the memory access time compared to random interleavers.

In an alternative embodiment, rather than specifying the K prime numbers to define the shifts, the interleavers can be defined by specifying J different shifts for each interleaver. This embodiment would typically require the coder or decoder to store and access K×J shifts, however this is still a lower memory requirement compared to random interleavers.

In order improve the error detection/correction, it may be desirable to avoid the same shift for the same column in two different interleavers. After the shift matrix (S^{k}) is generated, each column in the shift matrix may be reviewed to determine if any two shifts in a column are the same. If a column has same shift for two different interleavers, the entries of the two columns may be swapped in one of the interleavers. See, for example, the shift matrix illustrated in FIG. 3C, in which it has been determined that two of the shifts (i.e., S₂² and S₂⁴) in the shift matrix are the same. This may be remedied by swapping two of the shifts (i.e., S₁⁴ and S₂⁴) in the same interleaver (i.e., the fourth interleaver). After the swap, the shift matrix should again be reviewed to determine if any two shifts in a column are the same. It should be noted that a careful choice of prime numbers may help in avoiding having the same shift for the same column in two different interleavers.

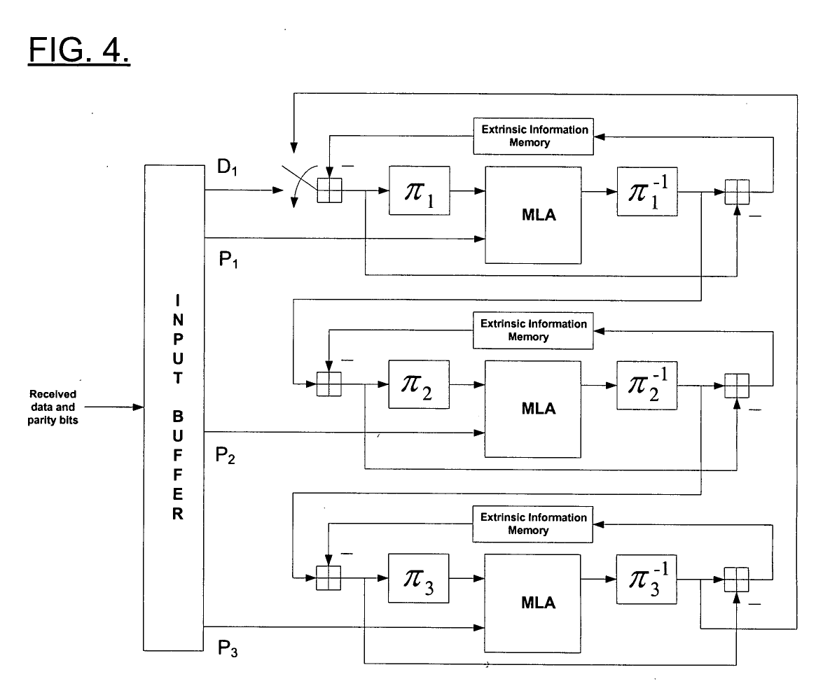

Referring now to FIG. 4, a functional block diagram of a receiver with an iterative Zigzag decoder is illustrated, according to an exemplary embodiment of the invention. The Zigzag decoder of FIG. 4 is a known type of iterative decoder, using a Max-Log APP algorithm to decode the received data. However, the interleavers (π₁, π₂, π₃) would be the same structured interleavers as discussed above regarding the decoder of FIG. 2, and the de-interleavers (π₁⁻¹, π₂⁻¹, π₃⁻¹) would be the inverse of the structured interleavers as discussed above. As such, the decoder of FIG. 4 would typically only need to store and/or access a prime number for each interleaver or J different shifts for each interleaver, as discussed above. As in the Zigzag encoder discussed above, such a decoder significantly lower the storage requirement and the memory access time compared to random interleavers. In the decoder of FIG. 4, the data bits and the parity bits are received in an input buffer. The data bits are interleaved using the first structured interleaver π₁, The interleaved data bits and the first set of parity bits P₁ are analyzed using the MLA algorithm. The data bits are then de-interleaved using the first de-interleaver π₁⁻¹. The data bits are then interleaved using the second structured interleaver π₂. The interleaved data bits and the second set of parity bits P₂ are analyzed using the MLA algorithm. The data bits are then de-interleaved using the second de-interleaver π₂⁻¹. The data bits are then interleaved using the third structured interleaver π₃. The interleaved data bits and the third set of parity bits P₃ are analyzed using the MLA algorithm. The data bits are then de-interleaved using the third de-interleaver π₃⁻¹. At each stage of the decoding, extrinsic information is obtained which increases the likelihood of correctly decoding the received data bits. Although FIG. 4 illustrates a Zigzag decoder using three interleavers/de-interleavers, the decoder of FIG. 4 could be expanded to use any number of interleavers/de-interleavers, and the number of interleavers/de-interleavers in the decoder would typically match the number of interleavers in the encoder.

The interleaver operation can be implemented in hardware, software, or a combination. The interleaver can be implemented on hardware, such as a digital signal processor or microprocessor, using simple operations. The interleaver can be implemented using element-by-element serial processing or, advantageously, parallel processing of J columns. A block-serial approach may also be implemented. One proposed embodiment of a structured interleaver improves parallelism in the zigzag decoding. The interleavers and de-interleavers can be implemented using simple multiplexers or barrel shifters, thus significantly reducing the latency. A massively parallel or a block-serial architecture may also be implemented. Further, when applied in conjunction with LDPC-like scheme, very high throughput architecture can be obtained.

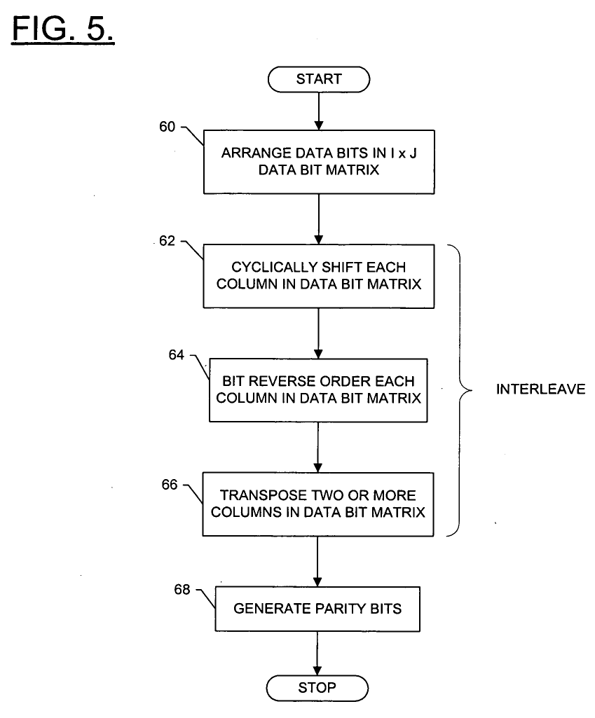

FIG. 5 is a flowchart of the operation of concatenated zigzag coding of data bits using a structured interleaver, according to an exemplary embodiment of the invention. Data bits are arranged into a data bit matrix that has I rows and J columns (I×J), such as by the processing element 14 of FIG. 1. See block 60. The data bit matrix is interleaved using a structured interleaver. The interleaving may include different cyclic shifts of each column. See block 62. The interleaving may also include bit reverse ordering of each column. See block 64. The interleaving may also include swapping two or more complete columns. See block 66. The interleaved data bit matrix is then encoded, such as by the Zigzag encoder 18, using a known Zigzag encoding technique to generate a set of parity bits. See block 68. Blocks 62 through 68 would typically be repeated for each interleaver. The data bits and the generated parity bits may then be transmitted.

The method of concatenated zigzag coding of data bits using a structured interleaver may be embodied by a computer program product. The computer program product includes a computer-readable storage medium, such as the non-volatile storage medium, and computer-readable program code portions, such as a series of computer instructions, embodied in the computer-readable storage medium. Typically, the computer program is stored by a memory device and executed by an associated processing unit, such as the processing element of the server.

In this regard, FIG. 5 is a flowchart of methods and program products according to the invention. It will be understood that each step of the flowchart, and combinations of steps in the flowchart, can be implemented by computer program instructions. These computer program instructions may be loaded onto one or more computers or other programmable apparatus to produce a machine, such that the instructions which execute on the computer or other programmable apparatus create means for implementing the functions specified in the flowchart step(s). These computer program instructions may also be stored in a computer-readable memory that can direct a computer or other programmable apparatus to function in a particular manner, such that the instructions stored in the computer-readable memory produce an article of manufacture including instruction means which implement the function specified in the flowchart step(s). The computer program instructions may also be loaded onto a computer or other programmable apparatus to cause a series of operational steps to be performed on the computer or other programmable apparatus to produce a computer implemented process such that the instructions which execute on the computer or other programmable apparatus provide steps for implementing the functions specified in the flowchart step(s).

Accordingly, steps of the flowchart support combinations of means for performing the specified functions, combinations of steps for performing the specified functions and program instruction means for performing the specified functions. It will also be understood that each step of the flowchart, and combinations of steps in the flowchart, can be implemented by special purpose hardware-based computer systems which perform the specified functions or steps, or combinations of special purpose hardware and computer instructions.

Embodiments of the invention provide improvement over a random interleaver by defining a structured interleaver. The structured interleaver lowers the error floor for short to intermediate block lengths. Importantly, the structured interleaver provides parallelism in the Zigzag encoding and decoding process, significantly improving the overall decoder throughput. The interleaver can be generated on the fly and requires storage for only K prime numbers. The increased parallelism provided by the structured interleaver enables the use of Zigzag encoding for very high throughput applications.

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

That which is claimed:

1. A system for concatenated zigzag coding of a plurality of data bits arranged in a matrix of rows and columns, the system comprising:
a transmitter capable of interleaving the data bits by shifting the data bits in each of the columns by a different respective one of a plurality of predefined numbers, each predefined number being different from all other numbers in the plurality of predefined numbers, the transmitter comprising a zigzag encoder that is capable of generating the parity bits from the interleaved data bits, the transmitter further capable of transmitting the generated parity bits and the data bits; and
a receiver capable of receiving the parity bits and the data bits, the receiver further capable of decoding the received parity bits to detect or correct any errors in the received data bits.

2. The system of claim 1, wherein the transmitter is further capable of interleaving the data bits by bit reverse ordering the data bits in each of the columns.

3. The system of claim 1, wherein the transmitter is further capable of interleaving the data bits by swapping at least two columns of data bits.

4. The system of claim 1, wherein the transmitter shifts the data bits by cyclically shifting the data bits.

5. The system of claim 1, wherein the generated parity bits are a first set of parity bits, and wherein the transmitter is further capable of interleaving the data bits a second time by shifting the data bits in each of the columns by a different respective one of a second plurality of predefined numbers, each one of the second plurality of predefined numbers being different from all other numbers in the second plurality of predefined numbers, each one of the second plurality of predefined numbers being different than the one of the first plurality of predefined numbers used to shift the data bits in a corresponding column, and wherein the transmitter is further capable of generating a second set of parity bits from the second interleaved data bits using a zigzag encoder.

6. The system of claim 5, wherein the transmitter defines the first and second pluralities of predefined numbers by the equation S^{k}=mod([k, k+1, . . . J, 1, 2, . . . k−1]×Pₖ, I), in which k is the number of times the data bits are interleaved, J is the number of columns in the data bit matrix, I is the number of rows in the data bit matrix, and Pₖ is prime relative to I and less than I.

7. The system of claim 5, wherein the transmitter defines the first and second pluralities of predefined numbers by a shift matrix, wherein the number of columns in the shift matrix are equal to the number of columns in the data bit matrix, wherein the number of rows in the shift matrix are equal to the number of times the data bits are interleaved, and wherein each number in each column of the shift matrix is different from all other numbers in each respective column.

8. A transmitter for concatenated zigzag coding of a plurality of data bits arranged in a matrix of rows and columns, the transmitter comprising:
a processing element capable of interleaving the data bits by shifting the data bits in each of the columns by a different respective one of a plurality of predefined numbers, each predefined number being different from all other numbers in the plurality of predefined numbers, the processing element further capable of generating the parity bits from the interleaved data bits using a zigzag encoder, the processing element further capable of transmitting the generated parity bits and the data bits.

9. The transmitter of claim 8, wherein the processing element is further capable of interleaving the data bits by bit reverse ordering the data bits in each of the columns.

10. The transmitter of claim 8, wherein the processing element is further capable of interleaving the data bits by swapping at least two columns of data bits.

11. The transmitter of claim 8, wherein the processing element shifts the data bits by cyclically shifting the data bits.

12. The transmitter of claim 8, wherein the generated parity bits are a first set of parity bits, and wherein the processing element is further capable of interleaving the data bits a second time by shifting the data bits in each of the columns by a different respective one of a second plurality of predefined numbers, each one of the second plurality of predefined numbers being different from all other numbers in the second plurality of predefined numbers, each one of the second plurality of predefined numbers being different than the one of the first plurality of predefined numbers used to shift the data bits in a corresponding column, and wherein the processing element comprises a zigzag encoder that is capable of generating a second set of parity bits from the second interleaved data bits.

13. The transmitter of claim 12, wherein the processing element defines the first and second pluralities of predefined numbers by the equation S^{k}=mod([k, k+1, . . . J, 1, 2, . . . k−1]×Pₖ, I), in which k is the number of times the data bits are interleaved, J is the number of columns in the data bit matrix, I is the number of rows in the data bit matrix, and Pₖ is prime relative to I and less than I.

14. The transmitter of claim 12, wherein the processing element defines the first and second pluralities of predefined numbers by a shift matrix, wherein the number of columns in the shift matrix are equal to the number of columns in the data bit matrix, wherein the number of rows in the shift matrix are equal to the number of times the data bits are interleaved, and wherein each number in each column of the shift matrix is different from all other numbers in each respective column.

15. A receiver for receiving concatenated zigzag encoded parity bits for a plurality of data bits arranged in a matrix of rows and columns, the receiver comprising:
a processing element capable of receiving the data bits, the processing element further capable of receiving and decoding parity bits generated from data bits interleaved by shifting the data bits in each of the columns by a different respective one of a plurality of predefined numbers, each predefined number being different from all other numbers in the plurality of predefined numbers, the processing element further capable of using the decoded parity bits to detect or correct any errors in the received data bits.

16. The receiver of claim 15, wherein the processing element is further capable of decoding parity bits generated from data bits interleaved by bit reverse ordering the data bits in each of the columns.

17. The receiver of claim 15, wherein the processing element is further capable of decoding parity bits generated from data bits interleaved by swapping at least two columns of data bits.

18. The receiver of claim 15, wherein the processing element is further capable of decoding parity bits generated from data bits interleaved by cyclically shifting the data bits.

19. The receiver of claim 15, wherein the received parity bits are a first set of parity bits, wherein the processing element is further capable of receiving a second set of parity bits, wherein the processing element is further capable of decoding the second set of parity bits generated from data bits interleaved a second time by shifting the data bits in each of the columns by a different respective one of a second plurality of predefined numbers, each one of the second plurality of predefined numbers being different from all other numbers in the second plurality of predefined numbers, each one of the second plurality of predefined numbers being different than the one of the first plurality of predefined numbers used to shift the data bits in a corresponding column, and wherein the processing element is further capable of using the decoded second set of parity bits to detect or correct any errors in the received data bits.

20. The receiver of claim 19, wherein the first and second pluralities of predefined numbers are defined by the equation S^{k}=mod[k, k+1, . . . J, 1, 2, . . . k−1]×Pₖ, I), in which k is the number of times the data bits are interleaved, J is the number of columns in the data bit matrix, I is the number of rows in the data bit matrix, and Pₖ is prime relative to I and less than I.

21. The receiver of claim 19, wherein the first and second pluralities of predefined numbers are defined by a shift matrix, wherein the number of columns in the shift matrix are equal to the number of columns in the data bit matrix, wherein the number of rows in the shift matrix are equal to the number of times the data bits are interleaved, and wherein each number in each column of the shift matrix is different from all other numbers in each respective column.

22. A method for concatenated zigzag coding of a plurality of data bits arranged in a matrix of a plurality of rows and a plurality of columns, the method comprising:
interleaving the data bits by shifting the data bits in each of the columns by a different respective one of a plurality of predefined numbers, each predefined number being different from all other numbers in the plurality of predefined numbers; and
generating the parity bits from the interleaved data bits using a zigzag encoding technique.

23. The method of claim 22, wherein interleaving the data bits further comprises bit reverse ordering the data bits in each of the columns.

24. The method of claim 22, wherein interleaving the data bits further comprises swapping at least two columns of data bits.

25. The method of claim 22, wherein the data bits are cyclically shifted.

26. The method of claim 22, wherein the generated parity bits are a first set of parity bits, wherein the plurality of predefined numbers is a first plurality of predefined numbers, and wherein the method further comprises:
interleaving the data bits a second time by shifting the data bits in each of the columns by a different respective one of a second plurality of predefined numbers, each one of the second plurality of predefined numbers being different from all other numbers in the second plurality of predefined numbers, each one of the second plurality of predefined numbers being different than the one of the first plurality of predefined numbers used to shift the data bits in a corresponding column; and
generating a second set of parity bits from the second interleaved data bits using a zigzag encoding technique.

27. The method of claim 26, wherein the first and second pluralities of predefined numbers are defined by the equation: S^{k}=mod([k, k+1, . . . J, 1, 2, . . . k−1]×Pₖ, I), in which k is the number of times the data bits are interleaved, J is the number of columns in the data bit matrix, I is the number of rows in the data bit matrix, and Pₖ is prime relative to I and less than I.

28. The method of claim 26, wherein the first and second pluralities of predefined numbers are defined by a shift matrix, wherein the number of columns in the shift matrix are equal to the number of columns in the data bit matrix, wherein the number of rows in the shift matrix are equal to the number of times the data bits are interleaved, and wherein each number in each column of the shift matrix is different from all other numbers in each respective column.

29. A computer program product for concatenated zigzag coding of a plurality of data bits arranged in a matrix of a plurality of rows and a plurality of columns, the computer program product comprising at least one computer-readable storage medium having computer-readable program code portions stored therein, the computer-readable program code portions comprising:
a first executable portion capable of interleaving the data bits by shifting the data bits in each of the columns by a different respective one of a plurality of predefined numbers, each predefined number being different from all other numbers in the plurality of predefined numbers; and
a second executable portion capable of generating the parity bits from the interleaved data bits using a zigzag encoding technique.

30. The computer program product of claim 29, wherein the first executable portion is further capable of interleaving the data bits by bit reverse ordering the data bits in each of the columns.

31. The computer program product of claim 29, wherein the first executable portion is further capable of interleaving the data bits by swapping at least two columns of data bits.

32. The computer program product of claim 29, wherein the first executable portion shifts the data bits by cyclically shifting the data bits.

33. The computer program product of claim 29, wherein the generated parity bits are a first set of parity bits, wherein the plurality of predefined numbers is a first plurality of predefined numbers, and wherein the computer program product further comprises:
a third executable portion capable of interleaving the data bits a second time by shifting the data bits in each of the columns by a different respective one of a second plurality of predefined numbers, each one of the second plurality of predefined numbers being different from all other numbers in the second plurality of predefined numbers, each one of the second plurality of predefined numbers being different than the one of the first plurality of predefined numbers used to shift the data bits in a corresponding column; and
a fourth executable portion capable of generating a second set of parity bits from the second interleaved data bits using a zigzag encoding technique.

34. The computer program product of claim 33, wherein the computer program product defines the first and second pluralities of predefined numbers by the equation: S^{k}=mod[k, k+1, . . . J, 1, 2, . . . k−1]×Pₖ, I), in which k is the number of times the data bits are interleaved, J is the number of columns in the data bit matrix, I is the number of rows in the data bit matrix, and Pₖ is prime relative to I and less than I.

35. The computer program product of claim 33, wherein the computer program product defines the first and second pluralities of predefined numbers by a shift matrix, wherein the number of columns in the shift matrix are equal to the number of columns in the data bit matrix, wherein the number of rows in the shift matrix are equal to the number of times the data bits are interleaved, and wherein each number in each column of the shift matrix is different from all other numbers in each respective column.
